(19) United States
(12) Patent Application Publication
(10) Pub. No.: US 2016/0322198 A1
(43) Pub. Date: Nov. 3, 2016

(54) Ion Source for Metal Implantation and Methods Thereof

(71) Applicant: Infineon Technologies AG, Neubiberg (DE)

(72) Inventors: Ewald Wiltsche, Maria Saal (AT); Peter Zupan, Villach (AT); Werner Schustereder, Villach (AT); Moriz Jelinek, Villach (AT); Robert Eberwein, Villach (AT); Friedrich Kroener, Villach (AT)

(21) Appl. No.: 14/701,320

(22) Filed: Apr. 30, 2015

(51) Int. Cl. H01J 37/317; H01L 21/67; C23C 14/16; C23C 14/34; H01J 37/08; C23C 14/48

(52) U.S. Cl. CPC H01J 37/3171; H01J 37/08; C23C 14/48; C23C 14/16; C23C 14/34; H01L 21/67213

(57) ABSTRACT

An ion source for an implanter includes a first solid state source electrode disposed in an ion source chamber. The first solid state source electrode includes a source material coupled to a first negative potential node. A second solid state source electrode is disposed in the ion source chamber. The second solid state source electrode includes the source material coupled to a second negative potential node, and the first solid state source electrode and the second solid state source electrode are configured to produce ions to be implanted by the implanter.

### TECHNICAL FIELD

The present invention relates generally to ion implantation, and, in particular embodiments, to ion sources for metal implantation and methods thereof.

### BACKGROUND

Minority carrier life time is an important aspect of many semiconductor devices such as power MOSFETs, fast diodes, insulated gate bipolar transistors (IGBT), bipolar power transistors and thyristors. For example, long carrier life time can result in poor turn OFF characteristics for the device.

Conventional methods to tailor minority carrier life time include electron radiation, introduction of carrier life time reducing metals such as gold or platinum. Electron irradiation is not favored due to the damage to other components such as the dielectric layers by introducing charge states. Gold deposition also has disadvantages due to the increase in leakage currents. Therefore, platinum is conventionally used to adjust the minority carrier life time.

### SUMMARY

In accordance with an embodiment of the present invention, an ion source for an implanter includes a first solid state source electrode disposed in an ion source chamber. The first solid state source electrode includes a source material coupled to a first negative potential node. A second solid state source electrode is disposed in the ion source chamber. The second solid state source electrode includes the source material coupled to a second negative potential node, and the first solid state source electrode and the second solid state source electrode are configured to produce ions to be implanted by the implanter.

In accordance with another embodiment of the present invention, an ion implanter including an ion source chamber includes a gas inlet and an ion outlet, a plurality of solid state source electrodes for producing ions provided by the ion source, and an ion extraction electrode associated with the ion source chamber for extracting the ions from the chamber through the ion outlet.

In accordance with another embodiment of the present invention, a method of implanting metal ions includes providing a first solid state source electrode in an ion source chamber. The first solid state source electrode includes a source material coupled to a first negative potential node. The method further includes providing a second solid state source electrode disposed in the ion source chamber. The second solid state source electrode includes the source material and is coupled to a second negative potential node, and the first solid state source electrode and the second solid state source electrode are configured to produce ions to be implanted by the implanter. The method also includes generating the metal ions by sputtering atoms from the first solid state source electrode and the second solid state source electrode.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates an ion implantation apparatus in accordance with an embodiment of the present invention;

FIG. 1B illustrates a more specific example of the ion implantation apparatus in accordance with an embodiment of the present invention;

FIG. 2A illustrates a magnified cross-sectional view of an ion source in accordance with an embodiment of the present invention;

FIG. 2B illustrates a schematic working principle of an ion source in accordance with an embodiment of the present invention;

FIG. 2C illustrates a top view of the ion source in accordance with an embodiment of the present invention.

FIGS. 2D-2H illustrate alternative embodiments regarding the shapes of the solid source electrode and the auxiliary solid source electrode;

FIG. 3 illustrates an alternative cross-sectional view of an ion source in accordance with an embodiment of the present invention;

FIG. 4 illustrates an alternative cross-sectional view of an ion source having a number of auxiliary solid source electrodes greater than the number of auxiliary solid source electrodes in accordance with an embodiment of the present invention;

FIGS. 5A-5D illustrate different side views of different configurations of the auxiliary electrode relative to the solid source electrode in various embodiments of the present invention;

FIG. 6 illustrates a cross sectional view of an ion source showing structural aspects in accordance with an embodiment of the present invention;

FIG. 7A illustrates a cross sectional view of an ion source showing an alternative structural aspect in accordance with an embodiment of the present invention;

FIGS. 7B1 and 7B2 illustrate cross sectional views of an ion source showing an alternative structural aspect in accordance with an embodiment of the present invention, wherein FIG. 7B1 illustrates a front cross sectional view while FIG. 7B2 illustrates a side view;

FIG. 8 illustrate a cross-sectional view of an ion source showing a further structural aspect of the solid source electrodes in accordance with an embodiment of the present invention;

FIGS. 9A-9D illustrates embodiment shapes of the solid source electrode in accordance with embodiments of the present invention;

FIG. 10 illustrates a cross sectional view of an ion source in accordance with an embodiment showing a further alternative structural aspect of the present invention;

FIG. 11 illustrates a cross sectional view of an ion source including active cooling in accordance with an embodiment of the present invention;

FIG. 12A illustrates the change in ion beam current when the voltage of the auxiliary electrode and/or solid source electrode is changed in accordance with an embodiment of the present invention; and

FIG. 12B illustrates the change in ion beam current when the voltage of the auxiliary electrode and/or solid source electrode and arc current is changed in accordance with an embodiment of the present invention.

### DETAILED DESCRIPTION OF ILLUSTRATIVE EMBODIMENTS

Many types of high performance semiconductor devices require a very precisely defined charge carrier lifetime in the active device during the service life of the device. As described above, in many applications, platinum is used to reduce the carrier life time.

In conventional processes, platinum is deposited on the wafer surface and diffused into the wafer, and then the excess or unreacted platinum is removed from the surface. The diffusion process, which is controlled by the annealing process, is used to tailor the dose of platinum in-diffusing into the silicon wafer and therefore determines the doping profile of the platinum in silicon. However, such a process has many limitations including the inability to modulate the doping profile of the platinum.

For example, one of the limitations relates to the inability to produce retrograde profiles because in-diffusion profiles of platinum and other metals have a “U”-shaped profile. Similarly, the maximum concentration of platinum inside the wafer is limited by the solubility of platinum at the top surface. Further, high concentrations of platinum cannot be achieved without using a large thermal budget because higher solubility needed to increase the maximum concentration requires higher temperatures. However, spatially local doping profiles cannot be achieved at higher temperature annealing due to the large diffusivity of platinum at elevated temperatures.

Introduction of platinum using implantation can dramatically simplify this unit process because controlled amount of dose can be introduced within a narrow region of the silicon wafer. However, there is no commercial process for platinum implantation because of the absence of efficient implantation techniques.

The primary difficulty is due to the absence of a source gas and a liquid source. The only available way to implant platinum is with the use of a solid electrode. However, conventional solid source implanters are unstable and do not provide a stable ion source. Therefore, conventional solid platinum ion sources for implanters provide only low beam currents due to low yield. In particular, commercial implantation processes require a steady stable source of ions to produce a high beam current needed to introduce large doses of platinum quickly. Further, such large doses have to be produced without negatively impacting the source lifetime. A low beam current will result in long implantation times, which significantly increases the cost of the implantation process relative to deposition processes.

The inventors of this application have found this is due to the improper control of the electric and magnetic field within the ion source chamber due to the fixed position of the solid source of platinum in the ion source of the implanter. Accordingly, as described in various embodiments, a conventional ion source and/or a conventional implanted are modified and improved to produce a stable ion source of platinum ions, which is suitable for semiconductor mass production.

As will be described below in various embodiments, the modifications include adding a plurality of solid source electrodes within the ion source chamber. The additional solid source electrodes are mounted to be electrically isolated from the ion source chamber and are connected to a separate power supply so that the plasma ions can be accelerated in the ion chamber with a desired and well-defined acceleration voltage in the direction of the solid source, which is sputtered producing metal atoms/ions. This increases the sputtering effect significantly and sufficient atoms of metal such as platinum can be provided for ionization by the plasma. Further modifications include using different compositions of the plasma (such as Ar, Kr, or BF3) and different parameters for the solid source electrodes.

Accordingly, in various embodiments, construction and operation of a highly efficient ion sputter source will be described. The embodiments of the present invention are applied to ion implantation but may be applied to other applications including sputtering and etching that require a heavy ion source.

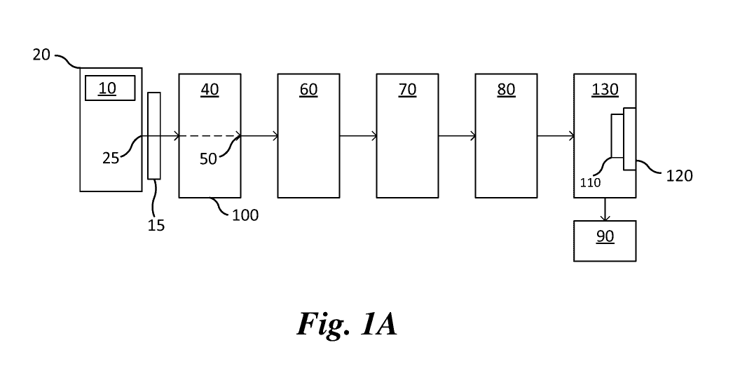

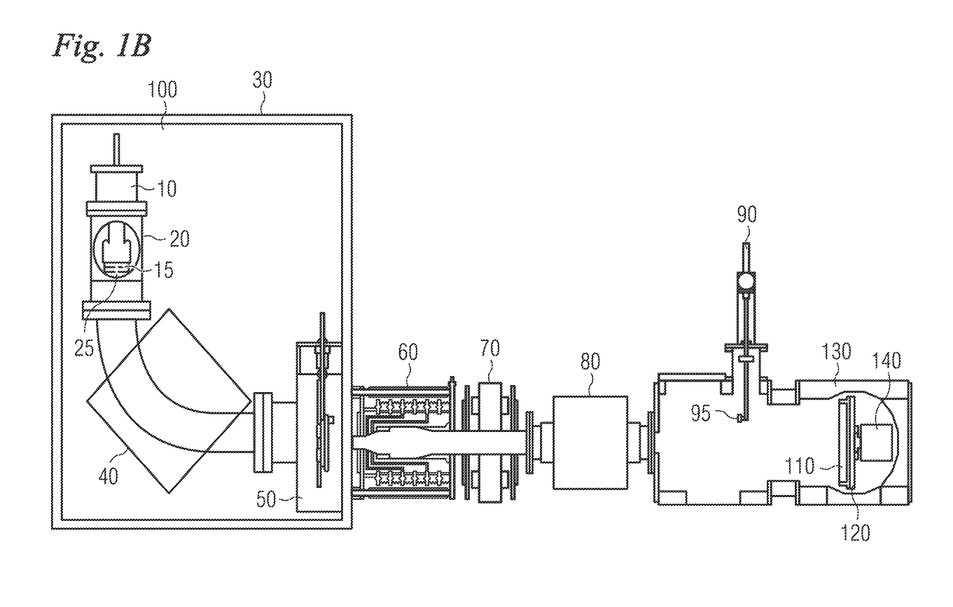

FIG. 1A illustrates an ion implantation apparatus in accordance with an embodiment of the present invention. FIG. 1B illustrates a more specific example of the ion implantation apparatus in accordance with an embodiment of the present invention.

Referring to FIGS. 1A and 1B, ions for implanting are generated in an ion source 10. In one embodiment, the ion source 10 is a Bernas ion source and will be described in more detail in various embodiments below. However, embodiments of the present invention may also be applied to other types of ion sources that use a solid source.

The ion source 10 is mounted within a chamber 20 and may be insulated from the chamber 20 so that the ion source 10 can be biased relative to the chamber 20, which is needed to generate the required extraction potential to extract the ions from the plasma generated within the chamber 20. The ion source 10 is voltage biased relative to the extraction electrodes 15. Therefore, ions are extracted from the chamber 20 through an aperture 25 and accelerated to an extraction velocity by the voltage bias between the chamber 20 and the extraction electrodes 15.

The extraction velocity and beam current may be adjusted by changing the voltage at the extraction electrodes 15, the ion source 10, and/or the size of the aperture 25, and the location of the extraction electrode 15 relative to the chamber 20. In illustrative embodiments, the ions extracted from the ion source 10 are accelerated to energies of about 0-60 keV, and about 30 keV-50 keV in one embodiment. The ions are maintained at the selected energy throughout the mass separation magnet assembly 40. Therefore, the mass separation magnet assembly 40 is maintained at uniform potential to prevent acceleration or deceleration, which would interfere with the mass separation.

Ions extracted from the ion source 10 are transported through the aperture 25 into the mass separation magnet assembly comprising an analyzing magnet. In a mass separation magnet assembly 40, the extracted ions are mass analyzed to remove ions having other masses than the ions that are being implanted. The mass analysis uses a balancing of the magnetic force exerted on the extracted ions by the magnetic field with their centrifugal force based on the extraction velocity. Thus, the ions adopt flight paths having a distinct radius of curvature dependent on the mass/charge ratio of the individual ions. Therefore, only ions having the flight path allowed by the mass separation magnet assembly 40 exit through the resolving aperture 50. The gap of the resolving aperture 50 is tailored to control ions having the specific mass/charge ratio or flight path.

The ions exiting the high voltage chamber 100 enter the accelerator tube 60, where they are accelerated to the implant energy. In illustrative embodiments, the ions are accelerated to energies of about 0 MeV to 10 MeV. For low energy implants, the accelerator tube 60 may not provide further acceleration. The accelerator tube 60 is a linear accelerator in one embodiment.

The ions passing through the accelerator tube 60 enter the focusing assembly 70, which assists in diverging and converging, i.e., focusing the ion beams. The focusing assembly 70 may comprise magnetic quadrapole in one or more embodiments. Embodiments of the invention include focusing assembly 70 having a series of such magnetic quadrupoles.

After exiting the chamber 20, some of the ions may still be neutralized, i.e., loose their charge. Implantation of neutral ions is to be avoided because it results in unknown dose of the ions to be implanted. To avoid implantation of neutral species, a deviation in the travel path is introduced by an electrostatic scanner 80. In case, the beam path includes an inclination introduced by the electrostatic scanner 80, neutral atoms that are not deviated by the electrostatic scanner 80 are captured and prevented from impacting the wafer. In various embodiments, the electrostatic scanner 80 may include a separate X-scanner and a Y-scanner. The X-scanner introduces a deviation in the path of the charged ions towards an X-axis while the Y-scanner introduces a deviation in the path of the charged ions towards a perpendicular Y-axis.

The order of the accelerator tube 60, the focusing assembly 70, and the electrostatic scanner 80 may be different in alternative embodiments.

Wafer 110 to be implanted is mounted on a wafer holder 120 in the target chamber 130, and the target including the wafer holder 120 and the target chamber 130 are maintained at ground potential. However, to reduce the implant energy, the target may also be positively biased or deceleration of the ions may also take place in the beam line by applying deceleration voltage at certain apertures. The electrostatic scanner 80, optionally along with the motion of the wafer holder 120, e.g., using the mount 140, scans the ions into the wafer 110.

A Faraday cup 90 is used to measure the dose of the ions being implanted. The implant dose is measured by measuring the collected beam current (because of the charge of the ions) and integrating over time and normalized over the area of the collector 95. During the implantation process, the apparatus is maintained at very low pressure to avoid contamination, for example, using pumps (not shown).

Various modifications to the design of the ion implanter are possible and as such within the scope of the present invention, which describes the design of the ion source 10 generating the ions that are implanted into the wafer 110.

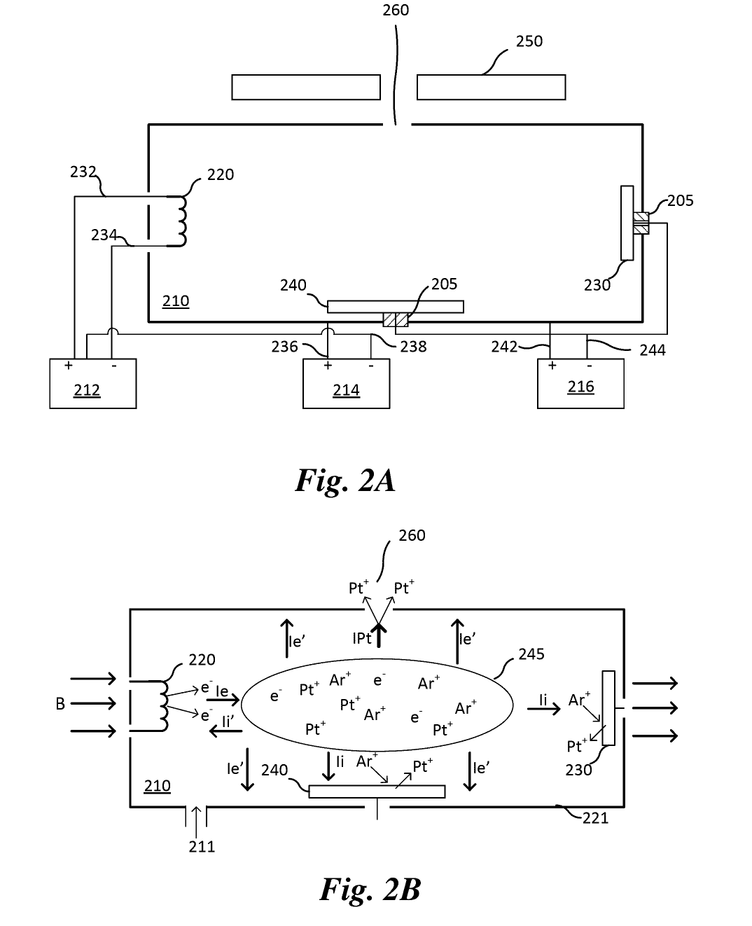

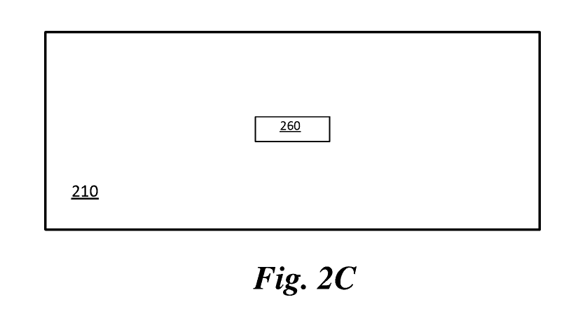

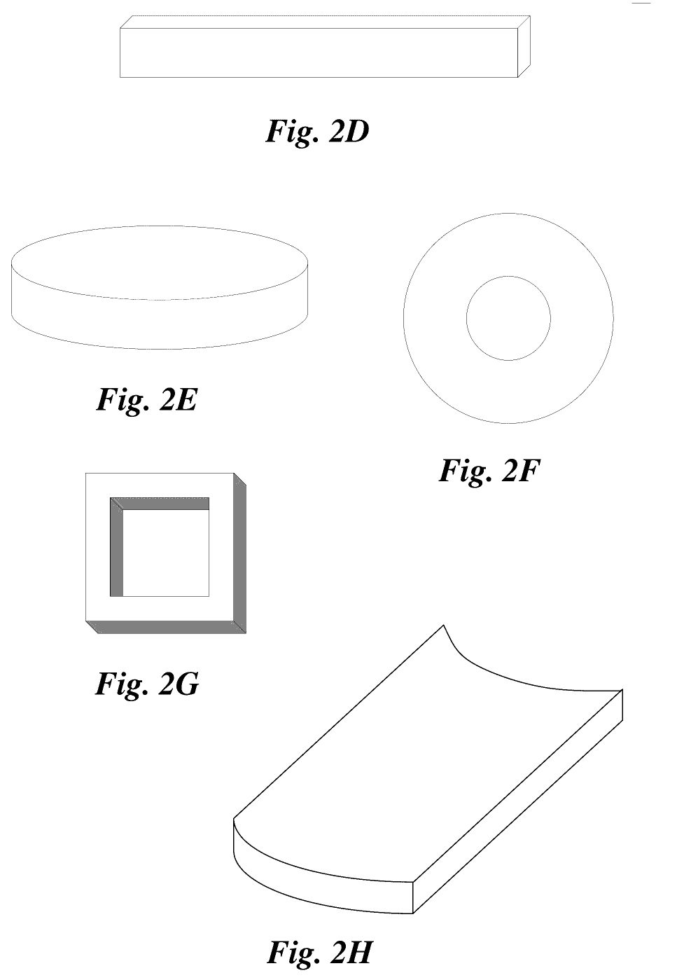

FIG. 2A illustrates a magnified cross-sectional view of an ion source in accordance with an embodiment of the present invention. FIG. 2A may be used as the ion source described in FIG. 1A or 1B. FIG. 2B illustrates a schematic working principle of the ion source. FIG. 2C illustrates a top view of the ion source in accordance with an embodiment of the present invention.

Referring to FIGS. 2A and 2B, the ion source chamber 210 comprises a thermionic gun 220 to generate electrons. The thermionic gun 220 comprises a hot cathode having a filament that is heated by the application of a filament heating current from the filament power supply 212 through the first filament conductor 232, which is coupled to a positive potential and the second filament conductor 234, which is coupled to a negative potential. The electrons emitted by the thermionic gun 220 may have energies of up to 100 eV or more.

The filament may be any suitable shape including a helical coil or pig-tail filament having a uniform cross-section, a ribbon filament having a non-uniform cross-section, a hair-pin filament, and others. In one or more embodiments, the thermionic gun 220 may also be heated indirectly. Embodiments of the present invention apply not only to Bernas sources in which the filament is in the form of a loop at one end of the ion source chamber 210 but also to Freeman sources in which the filament is in the form of a rod-like filament extending into the ion source chamber 210.

The ion source chamber 210 is powered by an arc power supply 214, which establishes an arc current between the thermionic gun 220 and the ion source chamber 210 so that the potential difference between the thermionic gun 220 and the ion source chamber 210 is approximately 20 V to 120 V. The arc power supply 214 is coupled to the filament power supply 212 to ensure that the ion source chamber 210 is maintained at a positive voltage relative to the thermionic gun 220.

In conventional Bernas sources, a tungsten repeller is disposed directly across the thermionic gun 220 and a floating platinum source is introduced. Such designs result in poor ionization efficiency and as such not acceptable for commercial production. However, in various embodiments of the present invention, the tungsten repeller is replaced with a platinum solid state source electrode 230.

The ion source chamber 210 further includes one or more auxiliary solid source electrodes 240 electrically isolated from the ion source chamber 210. In various embodiments, the one or more auxiliary solid source electrodes 240 and the solid source electrode 230 comprise an exposed surface that is formed of the same material, which is the metal ion being generated for the implantation. For example, both the one or more auxiliary solid source electrodes 240 and the solid source electrode 230 have a top layer or coating comprising platinum. The platinum may be pure platinum or may be in an alloy or compound form. Alternatively, in another embodiment, the one or more auxiliary solid source electrodes 240 and the solid source electrode 230 comprise a single block of a platinum alloy or a platinum compound with non-metals.

In various embodiments, the solid source electrode 230 and the one or more auxiliary solid source electrodes 240 are negatively biased relative to the ion source chamber 210 by the solid source power supply 216 using the positive solid source conductor 242 and the negative solid source conductors 244. In various embodiments, the solid source electrode 230 and the one or more auxiliary solid source electrodes 240 are isolated from the ion source chamber 210 with one or more insulator regions 205.

In various embodiments, the positions of the solid source electrode 230 and the one or more auxiliary solid source electrodes 240 may be adjustably mounted within the ion source chamber 210.

The platinum ions generated from the ion source chamber 210 are extracted from the ion source opening 260. In one embodiment, the one or more auxiliary solid source electrodes 240 are located centrally opposite to the ion source opening 260.

An extraction electrode 250 is used to extract the platinum ions generated within the plasma 245. The extraction electrode 250 is used to extract out a beam of ions from the ion source chamber 210, and more specifically from the plasma 245. The extraction electrode 250 is constructed by a single sheet electrode in the illustrated example although in other embodiments, the extraction electrode 250 may include a plurality of electrode sheets.

Gas feed lines 211 introduce gas to be ionized into the ion source chamber 210. The gas may be an inert gas such as argon, xenon, krypton, and others.

The source magnetic field is externally applied and oriented parallel to the sidewalls 221 of the ion source chamber 210. The energetic primary electrons that produce ions are electromagnetically trapped in the horizontal direction comprising a Penning type of electron confinement. A good confinement increases the probability of collisions between the electrons and the gas atoms/molecules within the ion source chamber 210. The electron confinement results in ionization of the incoming gas forming a plasma 245.

The energetic electrons from the thermionic gun 220 ionize the gas atoms forming ions such as argon ions. The positive ions in the plasma 245 such as Ar+ are attracted and accelerated to the negatively charged solid source electrode 230 and the one or more auxiliary solid source electrodes 240 and sputter platinum atoms from the solid source electrode 230 and the one or more auxiliary solid source electrodes 240. Thus, the efficiency of generation of platinum ions is greatly increased in contrast to conventional designs in which the platinum is at a floating potential. This is because of the increased surface area of the solid source surface as well as the negative voltage that increases the impact velocity and density of the argon ions. Neutral platinum atoms may further be ionized once within the plasma 245.

Accordingly, the electron current Ie is directed from the thermionic gun 220 to the insides of the ion source chamber 210 while an electron current Ie′ flows from the plasma 245 to the walls of the ion source chamber 210. Because of the negative voltage on the solid source electrode 230 and the one or more auxiliary solid source electrodes 240, the ions in the plasma 245 flow towards them as ion current Ii but some ion current Ii′ may also flow towards the filament of the thermionic gun 220, which would lower the life time of the filament, e.g., due to sputtering.

FIGS. 2D-2H illustrate alternative embodiments of the shapes for the solid source electrode and the auxiliary solid source electrode.

In various embodiments, the shape of the solid source electrode and the auxiliary solid source electrode may be varied to obtain the best sputtering efficiency. The sputtering efficiency of the system is significantly influenced by the shape and the surface of the solid source electrodes.

FIG. 2D illustrates a cuboidal shaped solid source electrode, FIG. 2E illustrates a circular or cylindrical solid source electrode, FIG. 2F illustrates a donut or concentric shaped solid source electrode, and FIG. 2G illustrates a frame shaped solid source electrode. The frame shaped solid source electrode is any generic shape with a central opening. In one embodiment, the frame shaped solid source is a square or rectangle, while in other embodiments it may also be circular (concentric), oval, or other non-standard shapes.

In further embodiments, the solid source electrode may have a partial cut of a solid surface. For example, the solid source electrode may be a portion of a concentric cylinder so that a concave surface is formed as illustrated in FIG. 2H. Such rounded surfaces may optimize the distance between the plasma confinement and the solid source electrode or auxiliary solid source electrode, e.g., establish equidistance between the plasma confinement and the solid source electrode or auxiliary solid source electrode. In addition, rounded surfaces reduce concentrations in electrical and magnetic field lines and therefore improve sputtering efficiency without compromising source lifetime by avoiding hot-spots.

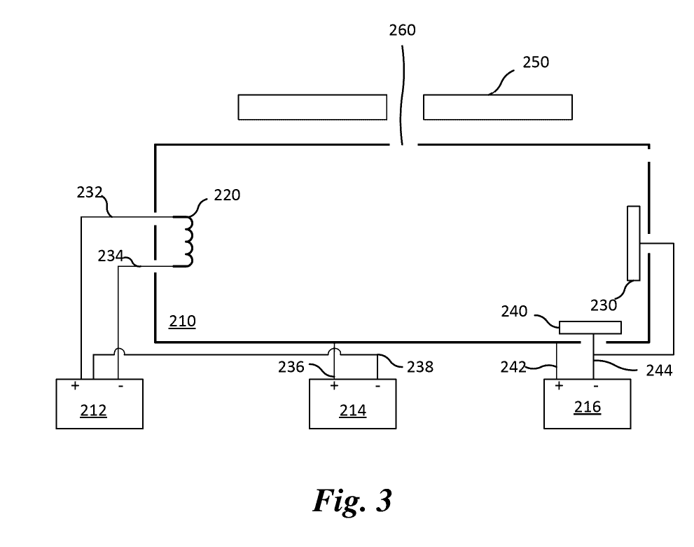

FIG. 3 illustrates an alternative cross-sectional view of an ion source in accordance with an embodiment of the present invention.

Embodiments of the present invention include varying the location of the solid source within the ion source chamber 210. For example, the one or more auxiliary solid source electrodes 240 may be located towards a horizontal edge of the ion chamber source rather than being centrally located as illustrated in FIG. 2. In various embodiments, the location of the one or more auxiliary solid source electrodes 240 may be modified using a mechanical lever that positions the one or more auxiliary solid source electrodes 240 within the ion source chamber 210. For example, the position of the one or more auxiliary solid source electrodes 240 may be varied depending on the implant energy and dose selected for the implantation. When the one or more auxiliary solid source electrodes 240 is placed nearer to the thermionic gun 220 (without changing the voltage on the one or more auxiliary solid source electrodes 240), the electric field density increases resulting in a larger sputter yield.

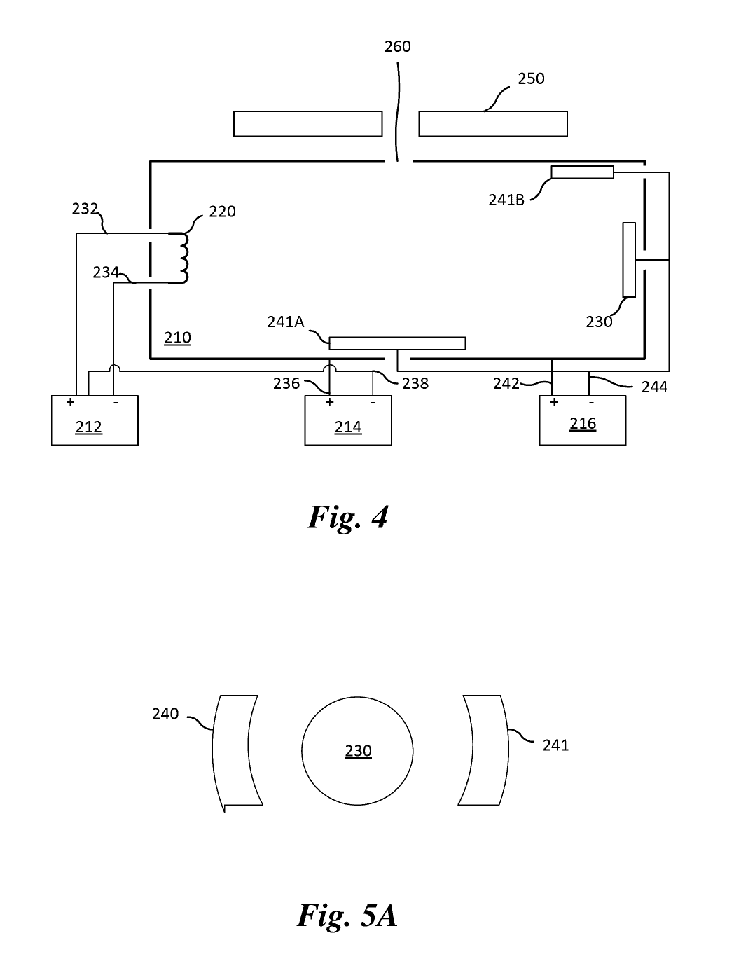

FIG. 4 illustrates an alternative cross-sectional view of an ion source having more auxiliary solid source electrodes than the solid source electrodes in accordance with an embodiment of the present invention.

As referred in prior embodiments, more than one auxiliary electrode may be used in various embodiments. As clearly illustrated in FIG. 4, a first auxiliary electrode 241A and a second auxiliary electrode 241B are disposed in the ion source chamber 210. In the illustrated embodiment, the first auxiliary electrode 241A is centrally located while the second auxiliary electrode 241B is located at an edge of the ion source chamber 210. However, this is only for illustration.

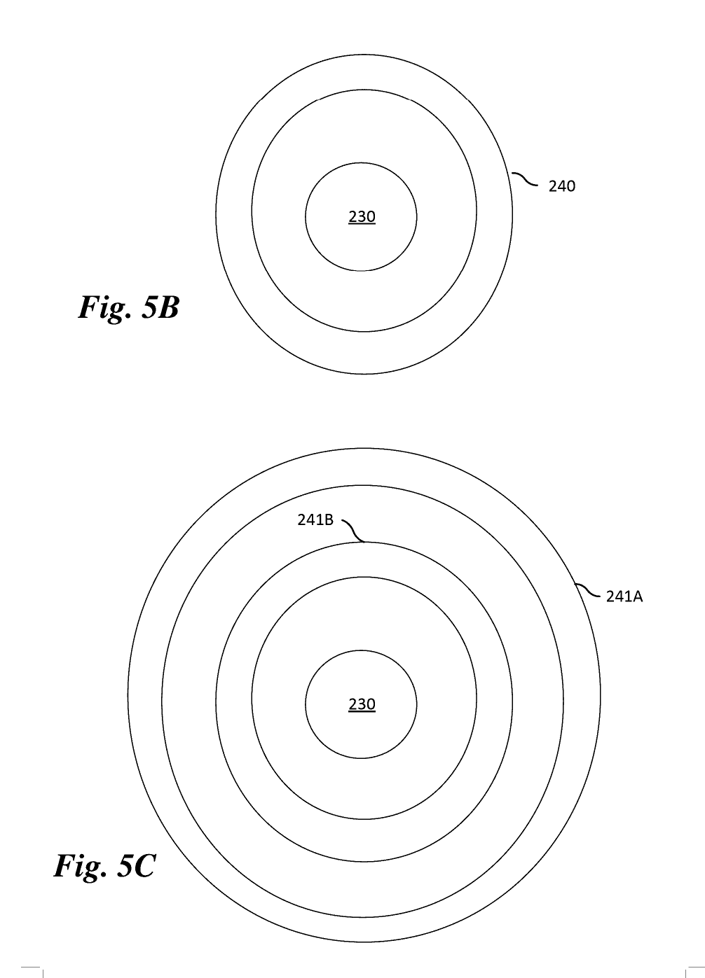

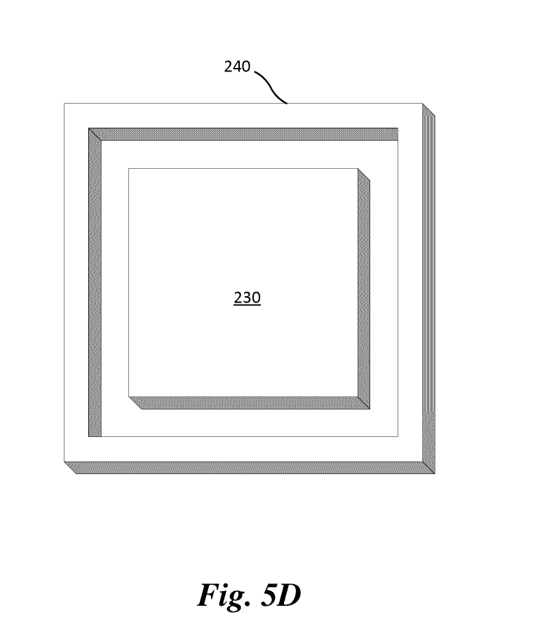

FIGS. 5A-5D illustrate different side views of different configurations of the auxiliary electrode relative to the solid source electrode in various embodiments of the present invention.

In various embodiments, the relative locations of the various solid source electrodes may be modified. As one illustration, in FIG. 5A, the one or more auxiliary solid source electrodes 240 are disposed around the edges of the solid source electrode 230. FIG. 5A illustrates the one or more auxiliary solid source electrodes 240 surrounding the solid source electrode 230 in two directions by forming a concave electrode while FIG. 5B illustrates a concentric placement.

Similarly FIG. 5C illustrates the first auxiliary electrode 241A surrounding the second auxiliary electrode 241B in another embodiment. FIG. 5D illustrates a further embodiment showing a square block forming the solid source electrode 230 and a frame shaped auxiliary solid source electrode 240.

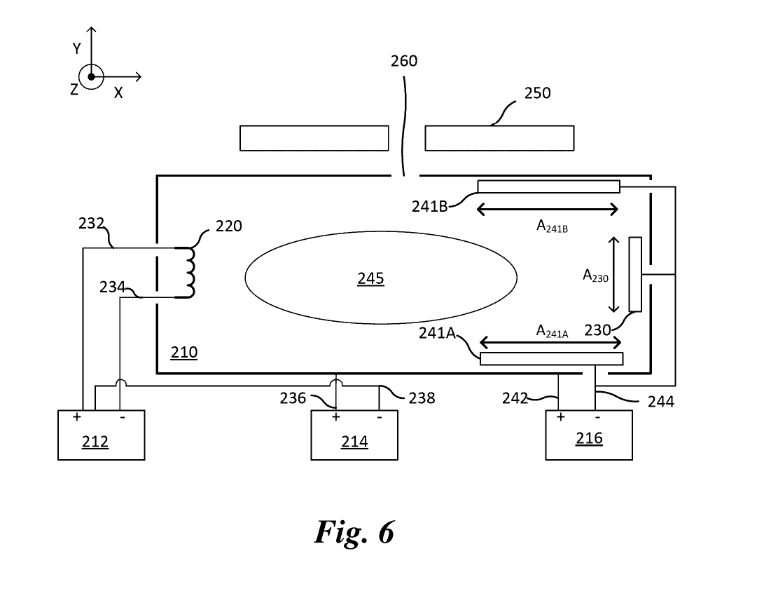

FIG. 6 illustrates a cross sectional view of an ion source in accordance with an embodiment showing structural aspects of the present invention.

In various embodiments, the location and size of the auxiliary electrodes is important as it modulates the electric field within the ion source chamber 210. Accordingly, in one or more embodiments, the location of each of the first auxiliary electrode 241A and the second auxiliary electrode 241B in the X-Y plane, which is the plane of the paper, may be optimized in one embodiment. Bringing the first auxiliary electrode 241A or the second auxiliary electrode 241B closer to the center along the X-axis increases the electric fields around the edges of the first auxiliary electrode 241A nearer to the plasma 245 resulting in more sputtering in those locations. Similarly, when the first auxiliary electrode 241A and the second auxiliary electrode 241B are centrally located (e.g., as shown in FIG. 2A), the solid source electrode 230 is sputtered less than the first auxiliary electrode 241A and the second auxiliary electrode 241B.

Accordingly, in various embodiments, the relative locations of the first auxiliary electrode 241A and the second auxiliary electrode 241B as well as the solid source electrode 230 are each configurable in all three planes. For example, the solid source electrode 230 may be moved closer to the plasma 245. In one embodiment, the relative locations of the first auxiliary electrode 241A and the second auxiliary electrode 241B are movable along the X axis and Y axis while the solid source electrode 230 is movable along the X-axis.

In one embodiment, the locations of each of the auxiliary electrode and the solid source electrode are selected based on the implant dose, i.e., the beam current required from the ion source.

Similarly, in another embodiment, the surface area of each of these electrodes is configurable. For example, the first surface area A_{241A} of the first auxiliary electrode 241A and the second surface area A_{241B} of the second auxiliary electrode 241B, and the surface area A₂₃₀ of the solid source electrode 230 may be independently changed.

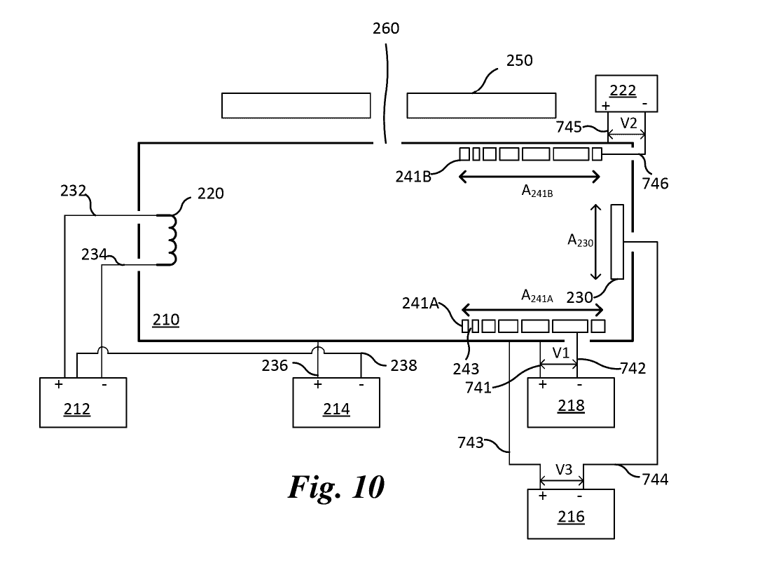

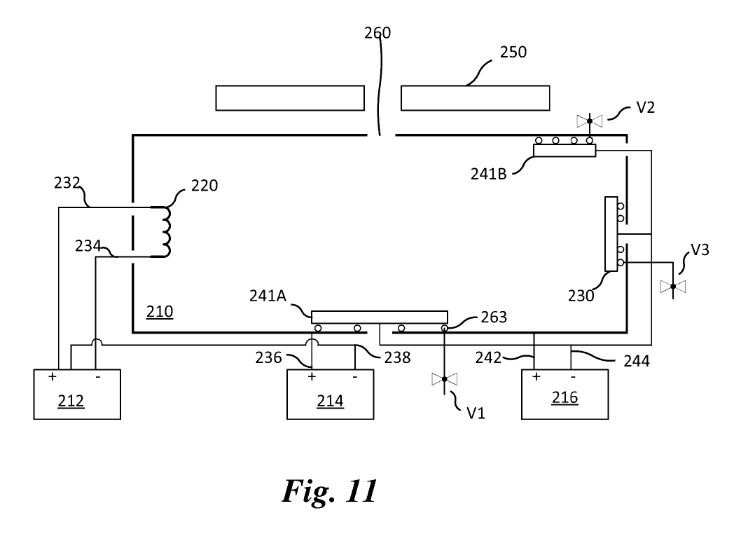

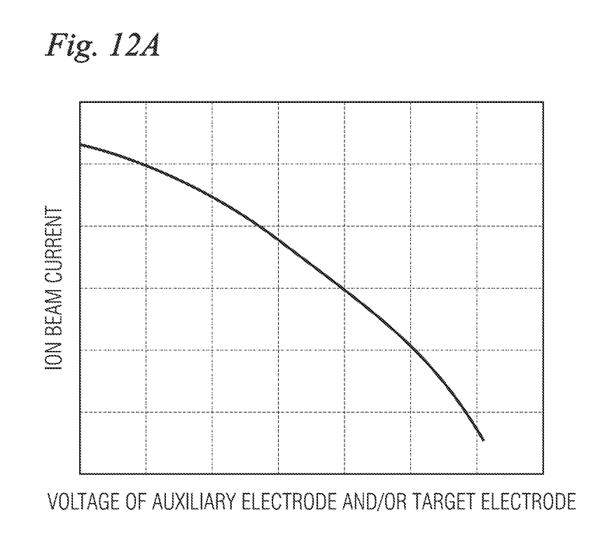

As will be illustrated in FIG. 10, each of the first auxiliary electrode 241A, the second auxiliary electrode 241B, and the solid source electrode 230 may be biased to a different potential.

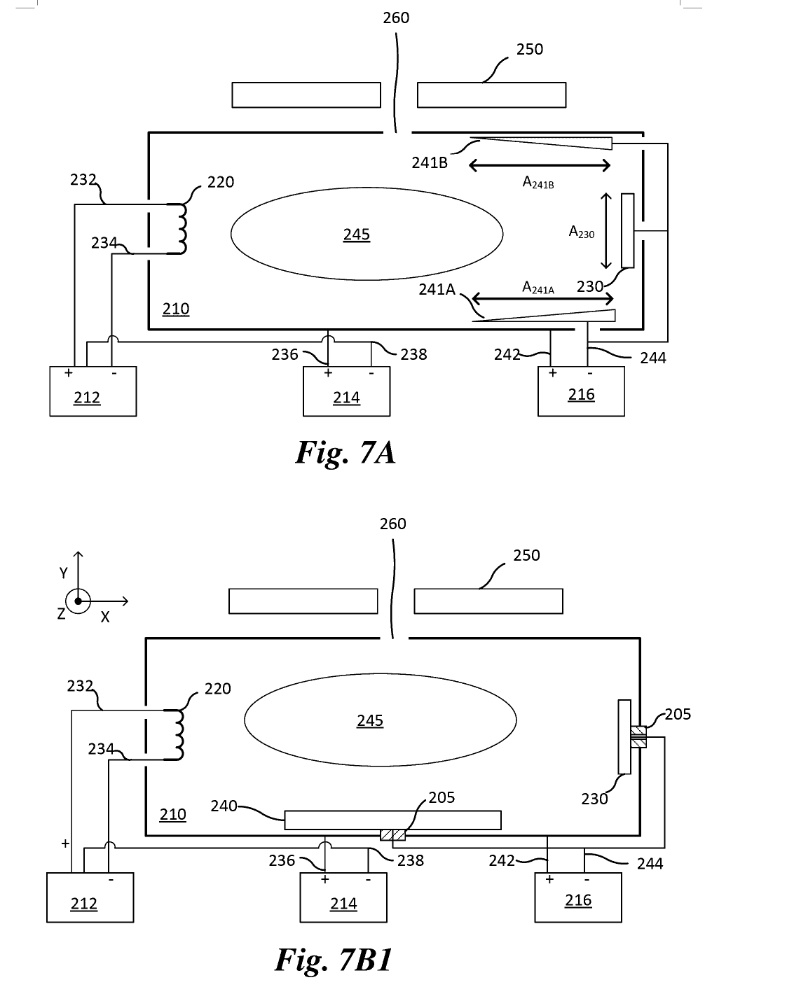

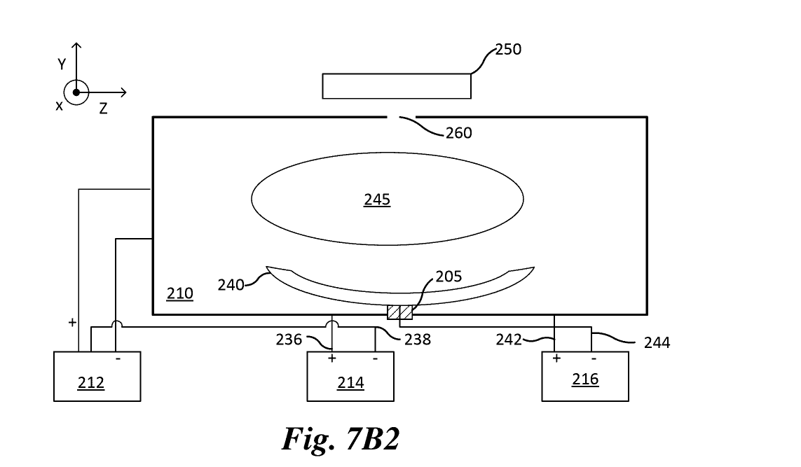

FIG. 7A illustrates a cross sectional view of an ion source in accordance with an embodiment showing an alternative structural aspect of the present invention.

In one or more embodiments, the shapes of the first auxiliary electrode 241A and the second auxiliary electrode 241B may be varied to produce a uniform electric and magnetic field within the ion source chamber 210. For example, in FIG. 7A, the thickness of the first auxiliary electrode 241A and the second auxiliary electrode 241B may be reduced towards the plasma 245.

FIGS. 7B1 and 7B2 illustrate cross sectional views of an ion source showing an alternative structural aspect in accordance with an embodiment of the present invention. FIG. 7B1 illustrates a front cross sectional view while FIG. 7B2 illustrates a side view.

In FIGS. 7B1 and 7B2, the shape of the auxiliary solid source electrode 240 is made to be more concave to maintain a constant distance to the plasma 245. For example, as illustrated in FIG. 7B2, in the y-z plane parallel to the side with the solid source electrode 230, the auxiliary solid source electrode 240 has a concave shape. In one or more embodiments, the solid source electrode 230 and/or the auxiliary solid source electrode 240 are shaped according to the plasma 245. However, the plasma 245 is not impacted by the shape of the solid source electrode 230 and/or the auxiliary solid source electrode 240.

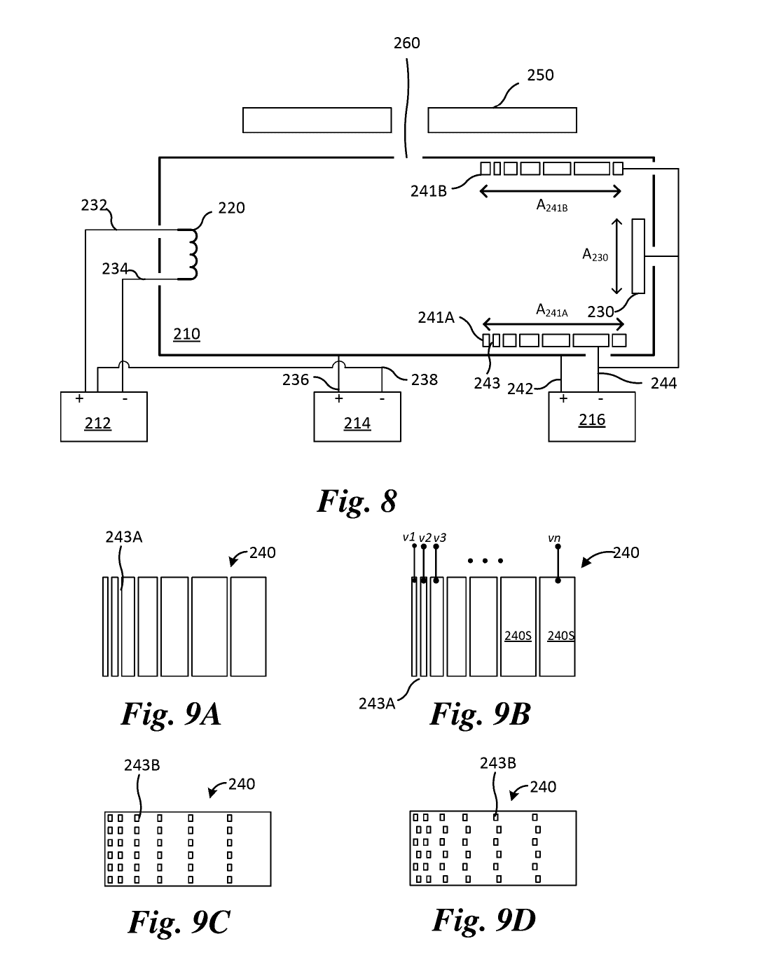

FIG. 8 illustrate a cross-sectional view of an ion source in accordance with an embodiment showing a further alternative structural aspect of the present invention.

In this embodiment, the shape of the auxiliary electrode is modified to increase or decrease the effective surface area. For example, in one embodiment, the auxiliary electrode comprises a plurality of gaps 243 separating the auxiliary solid source electrode 240 into multiple sections. The plurality of gaps 243 may have different configurations and may be modified to modulate and distribute the electric field within the ion source chamber 210. Alternatively, the plurality of gaps 243 is used to change the relative ratio of the surface area A_{241A} of the first auxiliary electrode 241A and the electric field adjacent the auxiliary electrode 240 as one illustration.

Although the solid source electrode 230 is not shown to include gaps, in various embodiments, the solid source electrode 230 may also include such gaps.

FIGS. 9A-9D illustrates embodiment shapes of the solid source electrode in accordance with embodiments of the present invention.

In various embodiments the gaps may be formed as trenches or holes. As an illustrated in FIGS. 9A and 9B, a plurality of trenches 243A is formed while in FIGS. 9C and 9D, a plurality of holes 243B are formed.

In one embodiment illustrated in FIG. 9B, the plurality of trenches 243A divides the auxiliary solid source electrode 240 into sections 240S, which are electrically isolated from each other within the auxiliary solid source electrode 240. Each section 240S of the auxiliary solid source electrode 240 may then be coupled to a different potential such as v1, v2, . . . vn. For example, in one embodiment, a variable resistor (or resistors having different fixed resistances) may be coupled between each section 240S of the auxiliary solid source electrode 240 and a power supply. The value of the resistors may be changed to adjust the electric field within the ion source chamber 210.

FIG. 9D illustrates an embodiment in which the plurality of holes 243B comprises rows of holes that are staggered relative to adjacent rows. Such an embodiment may be used to homogenize the perturbations in the electric field caused by the plurality of holes 243B.

FIG. 10 illustrates a cross sectional view of an ion source in accordance with an embodiment showing a further alternative structural aspect of the present invention.

In a further alternative embodiment, each of the solid source electrodes including the auxiliary electrodes are connected to a different power supply. Thus, as illustrated, the first auxiliary electrode 241A is coupled to the first auxiliary power supply 218 applying a first voltage V1 while the second auxiliary electrode 241B is coupled to the second auxiliary power supply 222 applying a second voltage V2. The solid source electrode 230 is coupled to the solid source power supply 216, which applies a third voltage V3. In various embodiments, the first voltage V1 is different from the second voltage V2 and the third voltage V3. Similarly, the second voltage V2 is different from the third voltage V3.

In one embodiment, the voltages are selected based on the implant dose, i.e., the beam current required from the ion source.

FIG. 11 illustrates a cross sectional view of an ion source including active cooling in accordance with an embodiment of the present invention.

In further embodiments, the ion source described above in various embodiments (FIGS. 2-10) may be modified further to include active cooling. Active cooling may be used to reduce the heating of the solid source electrode 230 and/or one or more auxiliary solid source electrodes such as the first auxiliary electrode 241A and/or the second auxiliary electrode 241B. As illustrated in FIG. 11, a cooling system with one or more cooling tubes 263 carrying a liquid coolant may be used to actively cool the solid source electrodes. In various embodiments, the flow of the coolant may be actively controlled or passively controlled. In one embodiment, the coolant may be switched on after a certain temperature is reached. Alternatively, the flow rate of the coolant may be increased if the local heating of one or more solid source electrodes or solid source electrode 230 is observed. In one or more embodiments, the flow rate of coolant may be individually controlled to each solid source. For example, a first control valve V1 regulates the flow of coolant to the first auxiliary electrode 241A, a second control valve V2 regulates the flow of coolant to the second auxiliary electrode 241B, and a third control valve V3 regulates the flow of coolant to the solid source electrode 230.

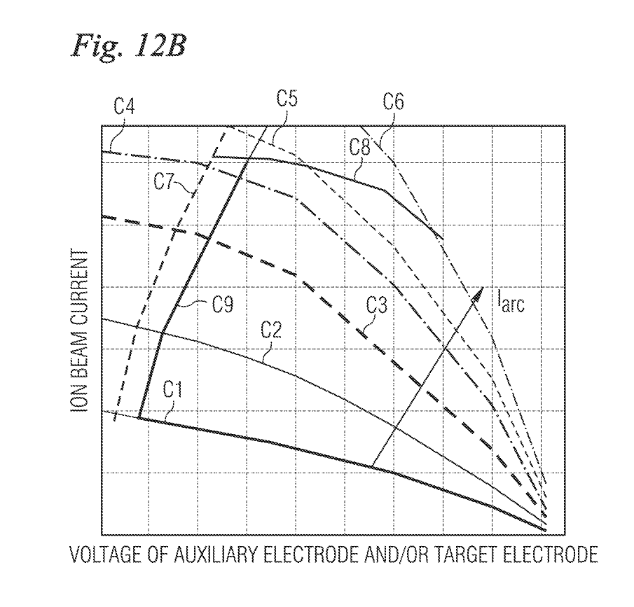

FIG. 12A illustrates the change in ion beam current when the voltage of the auxiliary electrode and/or solid source electrode is changed in accordance with an embodiment of the present invention.

Referring to FIG. 12A, as the voltage of the auxiliary electrode and/or solid source electrode is increased the ionization efficiency increases resulting in an increased ion beam current. While increasing the solid source voltage increases the ion beam current and efficiency, this is not an optimum solution as the higher solid source voltage results in increasing the electric field, which may result in breakdown of the system.

In various embodiments, the introduction of multiple solid source electrodes helps to minimize over-heating without compromising ion extraction efficiency or ion beam current. Accordingly a robust ion source chamber with increased source life time is achieved as described further using FIG. 12B.

FIG. 12B illustrates the change in ion beam current when the voltage of the auxiliary electrode and/or solid source electrode and arc current is changed in accordance with an embodiment of the present invention.

Referring to FIG. 12B, a larger arc current in the ion source chamber 210 results in melting of the solid source due to increased heating. This is illustrated in FIG. 12B, which shows a plurality of curves (C1, C2, C3, C4, C5, C6), with increasing arc current (I_{arc}). The higher arc current results in a greater ionization resulting in more ions in the plasma, which are accelerated towards the solid source electrodes including the auxiliary solid source electrode. Increasing the arc current therefore results in heating of the solid source electrode, which eventually melts. Such melting of the solid source electrodes dramatically reduces the life time of the solid source electrode (source life time) as well as may create a short circuit. In a further embodiment, to improve the life time of the solid source electrode and the one or more auxiliary solid source electrodes, they may be actively cooled, e.g., using a liquid coolant.

Accordingly, the seventh curve C7 shows the maximum allowable solid source voltage for each arc current. At higher arc current, the maximum allowable solid source voltage is lower. Similarly, the eighth curve C8 shows the maximum allowable arc current without melting the solid source electrode. As the solid source voltage is lowered, higher arc currents are allowable.

In various embodiments, the inventors of this invention have found that the best process window for increasing source life time and having a high ionization efficiency is to use the lowest possible arc current and the highest possible solid source voltage. Accordingly, the first curve C1 along with the ninth curve C9 illustrates the optimum process work curve for using the ion source in various embodiments. As illustrated, for low beam currents (e.g., low implant doses), the solid source voltage is modulated while keeping the arc current at the lowest value. For higher beam current requirements, the arc current is also increased.

The gas pressure is limited due to breakdown considerations and the stability of the plasma.

Although described above for the implantation of platinum, embodiments of the present invention may also be applied for implanting other elements including metals, dopants, and others. Examples include implantation of platinum, gold, silver, chromium, nickel, molybdenum, lead, hafnium, aluminum, iron, zinc, gadolinium, and others.

Embodiments of the present invention may include devices as well as processes and apparatuses used to fabricate the devices. One general aspect includes an ion source for an implanter. The ion source includes a first solid state source electrode disposed in an ion source chamber, the first solid state source electrode including a source material coupled to a first negative potential node; and a second solid state source electrode disposed in the ion source chamber. The second solid state source electrode includes the source material coupled to a second negative potential node, and the first solid state source electrode and the second solid state source electrode are configured to produce ions to be implanted by the implanter.

Implementations may include one or more of the following features. The ion source where the first solid state source electrode is facing an electron source and where the second solid state source electrode is inclined at an angle to the electron source. The ion source where the first solid state source electrode is centrally located under a slit for extracting ions. The ion source where the first solid state source electrode and the second solid state source electrode are located near a same sidewall of the ions source chamber. The ion source may further include a third solid state source electrode including the source material coupled to a third negative potential node. The ion source where the first solid state source electrode includes a cylindrical shaped electrode, a frame shaped electrode. The ion source where the first solid state source electrode surrounds the second solid state source electrode. The ion source where the first solid state source electrode surrounds the second solid state source electrode completely in a frame shaped manner. The ion source may further include a third solid state source electrode including the source material coupled to a third negative potential node, where the third solid state source electrode surrounds the first solid state source electrode and the second solid state source electrode. The ion source where the first solid state source electrode includes a plurality of gaps. The ion source where the first solid state source electrode includes a plurality of sections each configured to be connected to a different voltage node. The ion source where the first solid state source electrode is moveable within the ion source chamber. The ion source where the first solid state source electrode has a concave surface. The ion source where a thickness of the first solid state source electrode increases towards a sidewall of the ion source chamber. The ion source where the first negative potential node is configured to be coupled to a first voltage and the second negative potential node is configured to be coupled to a second voltage different from the first voltage. The ion source further including a cooling system configured to cool the first solid source electrode and the second solid source electrode. The ion source where the ions include a metal ion selected from the group including of platinum, gold, silver, chromium, nickel, molybdenum, lead, hafnium, aluminum, iron, zinc, and gadolinium. The ion implanter where the plurality of solid state source electrodes includes a first solid state source electrode coupled to a first voltage node and a second solid state source electrode coupled to a second voltage node. The ion implanter where at least one of the plurality of solid state source electrodes is facing an electron source and where at least one of the plurality of solid state source electrodes is inclined at an angle to a thermionic gun. The ion implanter where at least one of the plurality of solid state source electrodes is centrally located under a slit for extracting the ions. The ion implanter where the plurality of solid state source electrodes are located near a same sidewall of the ions source chamber. The ion implanter where at least one of the plurality of solid state source electrodes includes a cylindrical shaped electrode or a frame shaped electrode. The ion implanter where at least one of the plurality of solid state source electrodes includes a plurality of gaps. The ion implanter where the at least one of the plurality of solid state source electrodes includes a plurality of sections each configured to be connected to a different voltage node. The ion implanter where at least one of the plurality of solid state source electrodes is moveable within the ion source chamber. The ion implanter where at least one of the plurality of solid state source electrodes has a concave surface. The ion implanter where a thickness of at least one of the plurality of solid state source electrodes increases towards a sidewall of the ion source chamber. The ion implanter where the ions include metal ions. The ion implanter where the metal ions are selected from the group including of platinum, gold, silver, chromium, nickel, molybdenum, lead, hafnium, aluminum, iron, zinc, and gadolinium. The method further including: implanting a substrate using the generated metal ions. Implementations of the described techniques may include a method or process, or a device, or an apparatus.

Another general aspect includes an ion implanter including an ion source chamber including a gas inlet and an ion outlet, a plurality of solid state source electrodes for producing ions provided by the ion source, and an ion extraction electrode associated with the ion source chamber for extracting the ions from the chamber through the ion outlet.

Further implementations may include one or more of the following features. The ion implanter where the plurality of solid state source electrodes includes a first solid state source electrode coupled to a first voltage node and a second solid state source electrode coupled to a second voltage node. The ion implanter where at least one of the plurality of solid state source electrodes is facing an electron source and where at least one of the plurality of solid state source electrodes is inclined at an angle to a thermionic gun. The ion implanter where at least one of the plurality of solid state source electrodes is centrally located under a slit for extracting the ions. The ion implanter where the plurality of solid state source electrodes are located near a same sidewall of the ions source chamber. The ion implanter where at least one of the plurality of solid state source electrodes includes a cylindrical shaped electrode or a frame shaped electrode. The ion implanter where at least one of the plurality of solid state source electrodes includes a plurality of gaps. The ion implanter where the at least one of the plurality of solid state source electrodes includes a plurality of sections each configured to be connected to a different voltage node. The ion implanter where at least one of the plurality of solid state source electrodes is moveable within the ion source chamber. The ion implanter where at least one of the plurality of solid state source electrodes has a concave surface. The ion implanter where a thickness of at least one of the plurality of solid state source electrodes increases towards a sidewall of the ion source chamber. The ion implanter where the ions include metal ions. The ion implanter where the metal ions are selected from the group including of platinum, gold, silver, chromium, nickel, molybdenum, lead, hafnium, aluminum, iron, zinc, and gadolinium. The method further including: implanting a substrate using the generated metal ions. Implementations of the described techniques may include a method or process, or a device, or an apparatus.

Another general aspect includes a method of implanting metal ions, the method includes providing a first solid state source electrode in an ion source chamber, the first solid state source electrode including a source material coupled to a first negative potential node; and providing a second solid state source electrode disposed in the ion source chamber, where the second solid state source electrode includes the source material and is coupled to a second negative potential node, and where the first solid state source electrode and the second solid state source electrode are configured to produce ions to be implanted by the implanter; and generating the metal ions by sputtering atoms from the first solid state source electrode and the second solid state source electrode.

Implementations may include one or more of the following features. The method further including: implanting a substrate using the generated metal ions. Implementations of the described techniques may include a method or process, or a device, or an apparatus.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An ion source for an implanter, the ion source comprising:
a first solid state source electrode disposed in an ion source chamber, the first solid state source electrode comprising a source material coupled to a first negative potential node; and
a second solid state source electrode disposed in the ion source chamber, wherein the second solid state source electrode comprises the source material coupled to a second negative potential node, and wherein the first solid state source electrode and the second solid state source electrode are configured to produce ions to be implanted by the implanter.

2. The ion source of claim 1, wherein the first solid state source electrode is facing an electron source and wherein the second solid state source electrode is inclined at an angle to the electron source.

3. The ion source of claim 1, wherein the first solid state source electrode is centrally located under a slit for extracting ions.

4. The ion source of claim 1, wherein the first solid state source electrode and the second solid state source electrode are located near a same sidewall of the ions source chamber.

5. The ion source of claim 1, further comprising:
a third solid state source electrode comprising the source material coupled to a third negative potential node.

6. The ion source of claim 1, wherein the first solid state source electrode comprises a cylindrical shaped electrode, a frame shaped electrode.

7. The ion source of claim 1, wherein the first solid state source electrode surrounds the second solid state source electrode.

8. The ion source of claim 7, wherein the first solid state source electrode surrounds the second solid state source electrode completely in a frame shaped manner.

9. The ion source of claim 7, further comprising:
a third solid state source electrode comprising the source material coupled to a third negative potential node, wherein the third solid state source electrode surrounds the first solid state source electrode and the second solid state source electrode.

10. The ion source of claim 1, wherein the first solid state source electrode comprises a plurality of gaps.

11. The ion source of claim 10, wherein the first solid state source electrode comprises a plurality of sections each configured to be connected to a different voltage node.

12. The ion source of claim 1, wherein the first solid state source electrode is moveable within the ion source chamber.

13. The ion source of claim 1, wherein the first solid state source electrode has a concave surface.

14. The ion source of claim 1, wherein a thickness of the first solid state source electrode increases towards a sidewall of the ion source chamber.

15. The ion source of claim 1, wherein the first negative potential node is configured to be coupled to a first voltage and the second negative potential node is configured to be coupled to a second voltage different from the first voltage.

16. The ion source of claim 1, further comprising a cooling system configured to cool the first solid source electrode and the second solid source electrode.

17. The ion source of claim 1, wherein the ions comprise a metal ion selected from the group consisting of platinum, gold, silver, chromium, nickel, molybdenum, lead, hafnium, aluminum, iron, zinc, and gadolinium.

18. An ion implanter comprising:
an ion source chamber comprising a gas inlet and an ion outlet;
a plurality of solid state source electrodes for producing ions provided by the ion source; and
an ion extraction electrode associated with the ion source chamber for extracting the ions from the chamber through the ion outlet.

19. The ion implanter of claim 18, wherein the plurality of solid state source electrodes comprises a first solid state source electrode coupled to a first voltage node and a second solid state source electrode coupled to a second voltage node.

20. The ion implanter of claim 18, wherein at least one of the plurality of solid state source electrodes is facing an electron source and wherein at least one of the plurality of solid state source electrodes is inclined at an angle to a thermionic gun.

21. The ion implanter of claim 18, wherein at least one of the plurality of solid state source electrodes is centrally located under a slit for extracting the ions.

22. The ion implanter of claim 18, wherein the plurality of solid state source electrodes are located near a same sidewall of the ions source chamber.

23. The ion implanter of claim 18, wherein at least one of the plurality of solid state source electrodes comprises a cylindrical shaped electrode or a frame shaped electrode.

24. The ion implanter of claim 18, wherein at least one of the plurality of solid state source electrodes comprises a plurality of gaps.

25. The ion implanter of claim 24, wherein the at least one of the plurality of solid state source electrodes comprises a plurality of sections each configured to be connected to a different voltage node.

26. The ion implanter of claim 18, wherein at least one of the plurality of solid state source electrodes is moveable within the ion source chamber.

27. The ion implanter of claim 18, wherein at least one of the plurality of solid state source electrodes has a concave surface.

28. The ion implanter of claim 18, wherein a thickness of at least one of the plurality of solid state source electrodes increases towards a sidewall of the ion source chamber.

29. The ion implanter of claim 18, wherein the ions comprise metal ions.

30. The ion implanter of claim 29, wherein the metal ions are selected from the group consisting of platinum, gold, silver, chromium, nickel, molybdenum, lead, hafnium, aluminum, iron, zinc, and gadolinium.

31. A method of implanting metal ions, the method comprising:
providing a first solid state source electrode in an ion source chamber, the first solid state source electrode comprising a source material coupled to a first negative potential node; and
providing a second solid state source electrode disposed in the ion source chamber, wherein the second solid state source electrode comprises the source material and is coupled to a second negative potential node, and wherein the first solid state source electrode and the second solid state source electrode are configured to produce ions to be implanted by the implanter; and
generating the metal ions by sputtering atoms from the first solid state source electrode and the second solid state source electrode.

32. The method of claim 31, further comprising:
implanting a substrate using the generated metal ions.
